(19) United States
(12) Patent Application Publication
(10) Pub. No.: US 2008/0318351 A1
(43) Pub. Date: Dec. 25, 2008

(54) METHOD OF SETTING RECIPES OF A DEFECT TEST

(75) Inventors: Ho-Seong KANG, Gyeonggi-do (KR); Bong-Su KIM, Gyeonggi-do (KR); Young-Nam KIM, Gyeonggi-do (KR); Joung-Soo KIM, Gyeonggi-do (KR); Gee-Jun LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/870,344

(22) Filed: Oct. 10, 2007

(30) Foreign Application Priority Data
Oct. 10, 2006 (KR) 2006-0098212

(51) Int. Cl. H01L 21/02

(52) U.S. Cl. 438/16; 257/E21.527

(57) ABSTRACT

In a method of setting recipes of a defect test, a laser intensity map of a sample is obtained. The laser intensity map is then area-scanned to obtain average laser intensity. Recipes are set based on the average laser intensity. Thus, a laser power set in a defect detector may be constant regardless of inspectors so that the defect detector may have improved defect detection reliability.

### CROSS-REFERENCE TO RELATED APPLICATION

This application claims priority under 35 USC § 119 to Korean Patent Application No. 2006-98212, filed on Oct. 10, 2006, the contents of which are herein incorporated by reference in their entirety.

### BACKGROUND

1. Technical Field

Example embodiments of the present invention relate to a method of setting recipes of a defect test. More particularly, example embodiments of the present invention relate to a method of setting defect detection recipes in a defect detector for detecting defects in a semiconductor substrate.

2. Description of the Related Art

Generally, a semiconductor device may be manufactured by a deposition process, a photolithography process, an ion implantation process, a polishing process, a cleaning process, etc. After completing the above-mentioned processes, a plurality of defects such as a short, an open, etc., may be generated in the semiconductor device. The defects may have a detrimental effect on the operation and structure of the semiconductor device. Thus, to manage the defects in each of the processes, the defects may be detected using a defect detector.

To accurately detect defects in a semiconductor substrate using the defect detector, the setting of accurate defect detection recipes in the defect detector is required.

FIG. 1 is a flow chart illustrating a conventional method of setting defect detection recipes.

Referring to FIG. 1, in step S10, a laser intensity map of a sample by dies is obtained.

In step S20, a memory region and a logic region are set on the laser intensity map. Here, repetitive patterns are arranged in the memory region, and non-repetitive patterns are arranged in the logic region.

In step S30, as illustrated in FIG. 2, the memory region and the logic region are line-scanned to obtain a gray level, as shown in FIG. 3. When performing the line-scan, an inspector arbitrarily selects a point on the regions for the scan.

In step S40, a power of a laser that is used for testing a semiconductor substrate by gray levels is then adjusted.

However, according to the conventional method, the gray level is obtained by the line-scan process. That is, the inspector arbitrarily selects the point in the regions. The regions are then line-scanned on the basis of the selected point. Thus, when different inspectors select points that are different from each other, the obtained gray levels may also be different from each other. As a result, the defect detection recipes, i.e., the laser power values, may be set different from each other in the defect detector with respect to the same semiconductor substrate. When the defect detection process is carried out using the defect detector, defects on the semiconductor substrate may not be accurately detected because of the differently set laser power values.

Further, according to the conventional method, setting the defect detection recipes may require introducing the sample into the defect detector. This may cause a time delay of the defect detection recipes.

The present invention addresses these and other disadvantages of the conventional art.

### SUMMARY

Example embodiments of the present invention provide a method of setting unified recipes in a defect detector within a short time.

In a method of setting recipes of a defect test in accordance with one aspect of the present invention, a laser intensity map of a sample is obtained. The laser intensity map is then area-scanned to obtain average laser intensity. Recipes are set based on the average laser intensity.

### BRIEF DESCRIPTION OF THE DRAWINGS

The above and other features and advantages of the invention will become readily apparent by reference to the following detailed description when considered in conjunction with the accompanying drawings, wherein:

FIG. 1 is a flow chart illustrating a conventional method of setting recipes of a defect test;

FIG. 2 is a plan view illustrating a laser intensity map used for the method in FIG. 1;

FIG. 3 is a graph illustrating a gray level obtained from the laser intensity map in FIG. 2;

FIG. 4 is a flow chart illustrating a method of setting recipes of a defect test in accordance with an example embodiment of the present invention;

FIG. 5 is a picture showing a gray level of a memory region using the conventional method;

FIG. 6 is a picture showing a gray level of a memory region using a method in accordance with embodiments of the present invention;

FIG. 7 is a picture showing a gray level of a logic region using the conventional method;

FIG. 8 is a picture showing a gray level of a logic region using a method in accordance with embodiments of the present invention;

FIG. 9 is a plan view illustrating a semiconductor substrate on which defects detected by a defect detector using the conventional method are marked; and

FIG. 10 is a plan view illustrating a semiconductor substrate on which defects detected by a defect detector using a method in accordance with embodiments of the present invention are marked.

### DETAILED DESCRIPTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “includes” and/or “including,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

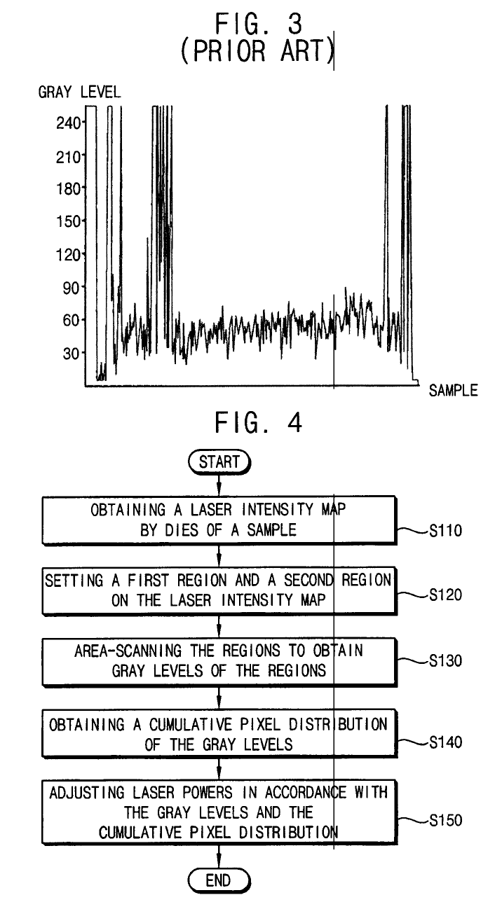

FIG. 4 is a flow chart illustrating a method of setting recipes of a defect test in accordance with an example embodiment of the present invention.

Referring to FIG. 4, in step S110, a laser intensity map by dies of a sample is obtained. In this example embodiment, a semiconductor substrate having a memory region and a logic region is used for the sample. Further, repetitive patterns may be arranged in the memory region, and non-repetitive patterns may be arranged in the logic region.

In step S120, a first region and a second region are set on the laser intensity map. Here, the first region corresponds to the memory region, and the second region corresponds to the logic region. Therefore, since the repetitive patterns are arranged in the first region and the non-repetitive patterns are arranged in the second region, it is necessary to set different laser powers with respect to the first region and the second region in a defect detector. For example, a laser power with respect to the first region has a gray level of about 30 to about 50. In contrast, a laser power with respect to the second region has a gray level of about 100 to about 120. Alternatively, when the sample may have regions without the above-mentioned characteristics, sectioning the laser intensity map by the regions may not be needed.

In step S130, average laser intensities with respect to the first region and the second region are then obtained. In this example embodiment, the first region and the second region are area-scanned to obtain gray levels of the first region and the second region. That is, according to this example embodiment, a specific point is not arbitrarily selected on the first region and the second region. In contrast, the first region and the second region are area-scanned. Thus, the obtained gray levels may not be different from each other when scanned by different inspectors.

In step S140, a cumulative pixel distribution of the gray levels is obtained. Here, the cumulative pixel distribution may be obtained from a ratio of gray level pixel numbers with respect to predetermined pixels of the first region and the second region.

In step S150, laser powers, which are used for inspecting the sample, are adjusted in accordance with the gray levels and the cumulative pixel distribution. The adjusted laser powers for the first region and the second region are then set in the defect detector.

In this example embodiment, the laser power with respect to the first region corresponding to the memory region may be adjusted to have the gray level of about 30 to about 50 and the cumulative pixel distribution of about 20%. Further, the laser power with respect to the second region corresponding to the logic region may be adjusted to have the gray level of about 100 to about 120 and the cumulative pixel distribution of about 25%.

According to this example embodiment, the laser intensity map is area-scanned to obtain the gray level. The cumulative pixel distribution with respect to the gray level is then obtained. The laser power is adjusted in accordance with the gray level and the cumulative pixel distribution. Thus, the laser power set in a defect detector may be constant regardless of the inspectors so that the defect detector may have improved defect detection reliability. Further, before introducing the sample into the defect detector, the inspection region of the sample may be area-scanned. Therefore, a time for setting the recipes in the defect detector may be significantly reduced.

Evaluating Reliability of Defect Detection Recipes

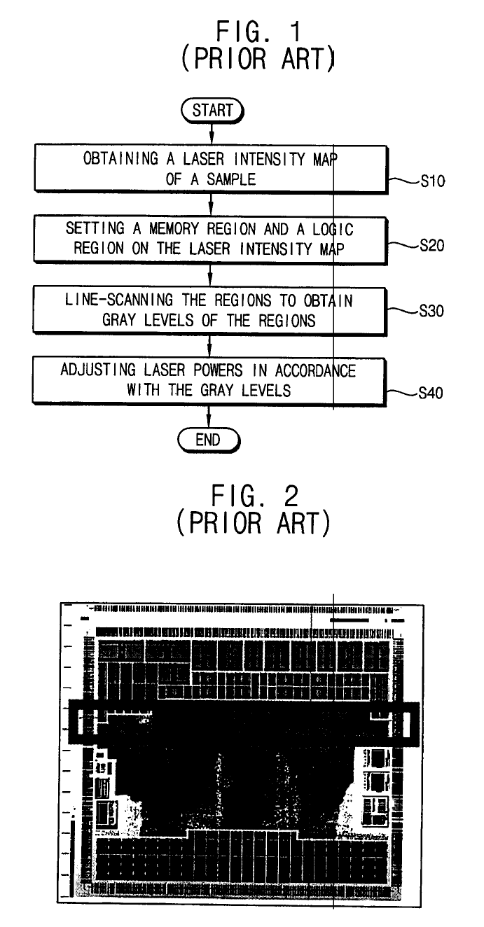

The conventional method illustrated with reference to FIG. 1 and the method of the present invention illustrated with reference to FIG. 4 were applied to a single semiconductor substrate having a memory region and a logic region to set defect detection recipes in a single defect detector. Defects generated on the semiconductor substrate were detected using the defect detector by each of the defect detection recipes.

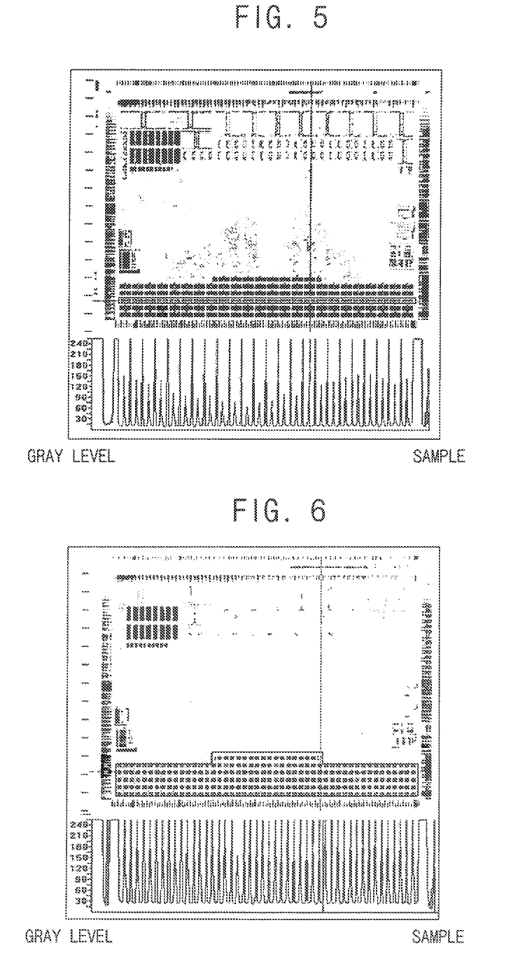

FIG. 5 is a picture showing a gray level of a memory region using the conventional method, and FIG. 6 is a picture showing a gray level of a memory region using a method in accordance with embodiments of the present invention.

As shown in FIGS. 5 and 6, although the semiconductor substrate has the same memory region, it can be noted that gray levels on the memory regions obtained using the conventional method and the method of the present invention are different from each other.

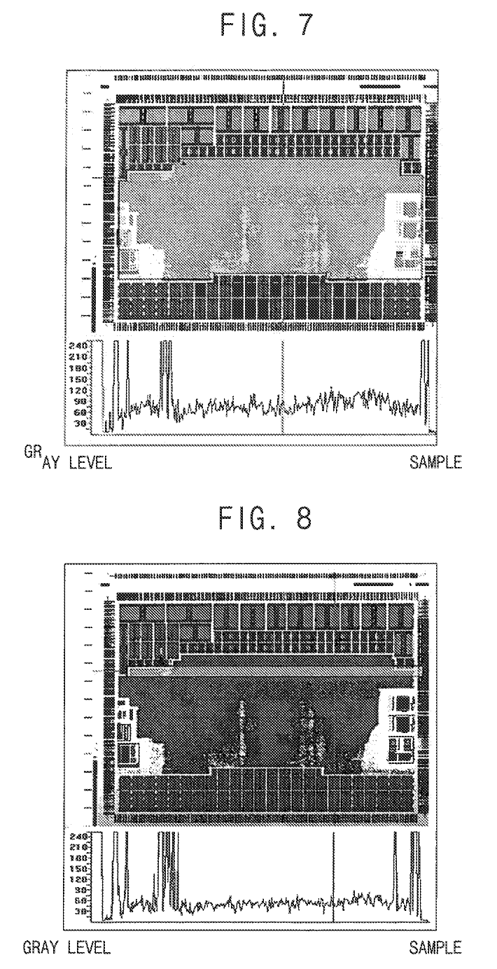

FIG. 7 is a picture showing a gray level of a logic region using the conventional method, and FIG. 8 is a picture showing a gray level of a logic region using a method in accordance with embodiments of the present invention. As shown in FIGS. 7 and 8, although the semiconductor substrate has the same logic region, it can be noted that gray levels on the logic regions obtained using the conventional method and the method of the present invention are different from each other.

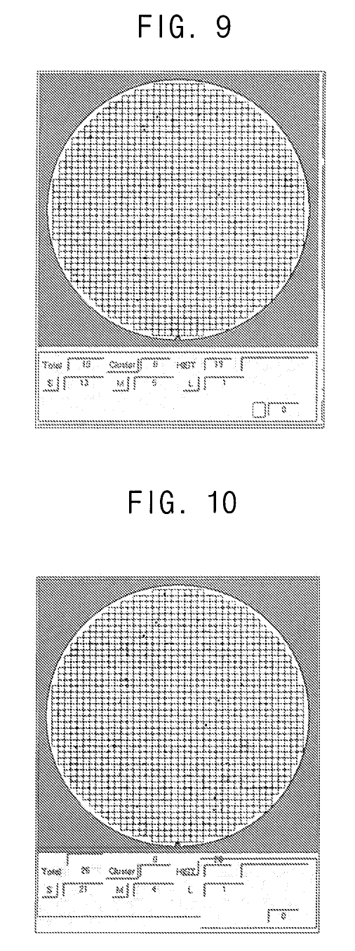

Therefore, when the defect detection recipe is set in the detect detector based on the measured values on FIGS. 5 and 7 as shown in FIG. 9, the defect detector detects nineteen defects on the semiconductor substrate.

In contrast, when the defect detection recipe is set in the detect detector based on the measured values on FIGS. 6 and 8 as shown in FIG. 10, the defect detector detects twenty-six defects on the semiconductor substrate.

As a result, the defect detection recipe set using embodiments of the present invention has a relatively better reliability compared to that set using the conventional method.

According to the present invention, the entire region of the sample, not a specific point of the sample, may be area-scanned. Thus, the laser power set in the defect detector may be constant regardless of the inspectors. As a result, the defect detector may have improved defect detection reliability.

Further, before introducing the sample into the defect detector, the inspection region of the sample may be area-scanned. Therefore, a time for setting the recipes in the defect detector may be significantly reduced.

In a method of setting recipes of a defect test in accordance with one aspect of the present invention, a laser intensity map of a sample is obtained. The laser intensity map is then area-scanned to obtain average laser intensity. Recipes are set based on the average laser intensity.

According to one example embodiment, the method may further include setting a first region in which a repetitive pattern is arranged, and a second region in which a non-repetitive pattern is arranged. Further, the first region and the second region may be independently area-scanned to obtain the average laser intensities by the first region and the second region.

According to another example embodiment, obtaining the average laser intensity may include obtaining gray levels of the first region and the second region, and obtaining a cumulative pixel distribution of the gray levels.

According to still another example embodiment, setting the recipes may include adjusting a laser power that is used for detecting defects of the sample in accordance with the gray levels and the cumulative pixel distribution.

In a method of setting recipes of a defect test in accordance with another aspect of the present invention, laser intensity maps with respect to a memory region and a logic region of a semiconductor substrate are obtained. The laser intensity maps are then area-scanned to obtain gray levels of the memory region and the logic region. Cumulative pixel distributions of the gray levels are obtained. Laser powers used for detecting defects in the memory region and the logic region of the semiconductor substrate are adjusted in accordance with the gray levels and the cumulative pixel distributions.

According to one example embodiment, adjusting the laser powers may include setting a first gray level with respect to the memory region, and setting a second gray level higher than the first gray level with respect to the logic region.

According to the present invention, the inspection region of the sample is area-scanned to obtain the gray level. The cumulative pixel distribution with respect to the gray level is then obtained. The laser power is adjusted in accordance with the gray level and the cumulative pixel distribution. Thus, the laser power set in a defect detector may be constant regardless of inspectors so that the defect detector may have improved defect detection reliability. Further, before introducing the sample into the defect detector, the inspection region of the sample may be area-scanned. Therefore, a time for setting the recipes in the defect detector may be remarkably curtailed.

Having described the preferred embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

What is claimed is:

1. A method of setting recipes of a defect test, comprising:
obtaining a laser intensity map of a sample;
area-scanning the laser intensity map to obtain an average laser intensity; and
setting recipes based on the average laser intensity.

2. The method of claim 1, further comprising setting a first region in which a repetitive pattern is arranged and a second region in which a non-repetitive pattern is arranged,
wherein the first region and the second region are independently area-scanned to obtain average laser intensities for the first region and the second region.

3. The method of claim 1, wherein obtaining the average laser intensity comprises:
obtaining a gray level of the laser intensity map; and
obtaining a cumulative pixel distribution of the gray level.

4. The method of claim 3, wherein setting the recipes comprises adjusting a laser power for inspecting defects of the sample in accordance with the gray level and the cumulative pixel distribution.

5. The method of claim 3, wherein the cumulative pixel distribution is obtained from a ratio of pixel numbers of the gray level with respect to pixel numbers of the sample.

6. The method of claim 1, wherein the sample comprises a semiconductor substrate having a memory region in which a repetitive pattern is arranged, and a logic region in which a non-repetitive pattern is arranged.

7. A method of setting recipes of a defect test, comprising:
obtaining laser intensity maps with respect to a memory region and a logic region of a semiconductor substrate;
area-scanning the laser intensity maps to obtain gray levels with respect to the memory region and the logic region;
obtaining cumulative pixel distributions with respect to the gray levels; and
adjusting a laser power for inspecting the memory region and the logic region of the semiconductor substrate based on the gray levels and the cumulative pixel distributions.

8. The method of claim 7, wherein the cumulative pixel distribution is obtained from a ratio of pixel numbers of the gray level with respect to pixel numbers of the sample.

9. The method of claim 7, wherein adjusting the laser powers comprises:
setting a first gray level with respect to the memory region; and
setting a second gray level higher than the first gray level with respect to the logic region.

10. The method of claim 9, wherein the first gray level is about 30 to about 50, and the second gray level is about 100 to about 120.
